(19) United States
(12) Patent Application Publication
(10) Pub. No.: US 2025/0286005 A1
(43) Pub. Date: Sep. 11, 2025

(54) SEMICONDUCTOR DEVICE, AND MANUFACTURING METHOD FOR SAME

(71) Applicant: Panasonic Intellectual Property Management Co., Ltd., Osaka (JP)

(72) Inventors: KIYOKAZU ITOI, Osaka (JP); DAISUKE SAKURAI, Osaka (JP)

(21) Appl. No.: 19/215,407

(22) Filed: May 22, 2025

Related U.S. Application Data
(63) Continuation of application No. PCT/JP2023/041045, filed on Nov. 15, 2023.

(30) Foreign Application Priority Data
Dec. 2, 2022 (JP) 2022-193412

(51) Int. Cl. H01L 23/00; H01L 21/48; H01L 23/498

(52) U.S. Cl. CPC H01L 24/11; H01L 21/4846; H01L 23/49811; H01L 23/49838; H01L 23/49894; H01L 24/10; H01L 24/13; H01L 24/742; H01L 2224/10125; H01L 2224/11462; H01L 2224/11464; H01L 2224/1155; H01L 2224/11618; H01L 2224/13007; H01L 2224/13017; H01L 2224/13019; H01L 2224/13023; H01L 2224/742; H01L 2924/3512; H01L 2924/381; H01L 2924/3841

(57) ABSTRACT

Semiconductor device (50) includes: semiconductor element (1) having a plurality of electrode terminals (2); bump (8) formed on each of the plurality of electrode terminals (2) and having tapering part (8a) that narrows with distance from a side close to corresponding one of electrode terminals (2); and buffer part (3c) covered with bump (8).

### TECHNICAL FIELD

The present disclosure relates to a semiconductor device and a method for manufacturing the semiconductor device.

### BACKGROUND ART

In recent years, to achieve both densification in semiconductor packaging and increase in number of pins of electrode terminals, a pitch between electrode terminals in a semiconductor element and an area of the electrode terminals have been reduced. As one of techniques for mounting such a semiconductor element on a mounting substrate, flip-chip mounting is known.

The flip-chip mounting is performed in which a protruding electrode called a bump is formed on an electrode terminal of a semiconductor element such as a system LSI, a memory, or a CPU. This bump is pressed against a connection terminal of the mounting substrate and heated. Consequently, the electrode terminal is connected to the connection terminal, and the semiconductor element is mounted on the mounting substrate.

For this purpose, a solder bump is often employed as the protruding electrode. To form the solder bump, there is a method using screen printing, dispensing, or electrolytic plating, for example. The solder bump is formed by disposing solder on the electrode terminal and heating the solder to a temperature equal to or higher than a melting point of the solder using a reflow furnace.

Unfortunately, as a pitch between electrode terminals is narrowed, a bridge failure is likely to occur in a pressure welding and heating step of the flip-chip mounting. This is a failure in which a melted and deformed solder bump is connected to another solder bump due to its surface tension. Thus, more rigorous demand for a narrower pitch causes more difficulty in employing the solder bump.

Alternatively, a method employing a tapered fine metal bump made of gold or copper, for example, instead of the solder bump as the protruding electrode is also known. This method includes a pressure welding and heating step of the flip-chip mounting, in which a distal end of the protruding electrode is plastically deformed, and the protruding electrode is bonded to the connection terminal by solid-phase diffusion. The metal bump is not melted in the step, so that a bridge failure due to melting and deformation of the metal bump can be prevented. In this regard, PTL 1 is known, for example.

### CITATION LIST

### Patent Literature

PTL 1: Japanese Patent No. 6154995

### SUMMARY OF THE INVENTION

The method using the fine metal bump causes stress applied to the bump to be applied to the connection terminal of the mounting substrate during mounting. As a result, a serious defect relating to reliability may occur, such as a crack occurring in a fragile layer under the connection terminal. The defect due to the stress during mounting may also occur on a side of the semiconductor element.

In view of the above, a technique for suppressing occurrence of a defect due to stress during mounting in flip mounting using a bump will be described below.

To solve the above problems, a semiconductor device of the present disclosure includes: a semiconductor element having a plurality of electrode terminals; a bump formed on each of the plurality of electrode terminals and having a tapering part narrowing with distance from a side close to the electrode terminal; and a buffer part covered with the bump.

A method for manufacturing a semiconductor device according to the present disclosure is performed on a semiconductor element including a plurality of electrode terminals and a resist layer covering each of the plurality of electrode terminals, the method including: a step of providing openings in the resist layer by inserting protrusions provided on an imprint die into the resist layer on the plurality of electrode terminals; a step of curing the resist layer by applying energy to the resist layer; a step of widening each of the openings in a width direction by causing the resist layer provided with the opening to react with a developer; and a step of forming a bump by filling the opening widened in the width direction with metal, the step of providing the openings being performed to cause a distal end of each of the protrusions to be prevented from reaching a surface of corresponding one of the electrode terminals to leave a gap.

The semiconductor device and the method for manufacturing the semiconductor device of the present disclosure allow a resist remnant to be disposed inside the bump, and thus enables a defect such as a crack to be suppressed by relieving stress during flip-chip mounting on the connection terminal.

### BRIEF DESCRIPTION OF THE DRAWINGS

FIG. 1 is a diagram illustrating an example of a semiconductor device of the present disclosure.

FIG. 2A is a diagram illustrating another example of the semiconductor device of the present disclosure.

FIG. 2B is a diagram illustrating yet another example of the semiconductor device of the present disclosure.

FIG. 2C is a diagram illustrating yet another example of the semiconductor device of the present disclosure.

FIG. 3A is a diagram for illustrating a method for manufacturing a semiconductor layer of the present disclosure.

FIG. 3B is a diagram for illustrating the method for manufacturing a semiconductor layer of the present disclosure.

FIG. 3C is a diagram for illustrating the method for manufacturing a semiconductor layer of the present disclosure.

FIG. 3D is a diagram for illustrating the method for manufacturing a semiconductor layer of the present disclosure.

FIG. 3E is a diagram for illustrating the method for manufacturing a semiconductor layer of the present disclosure.

FIG. 3F is a diagram for illustrating the method for manufacturing a semiconductor layer of the present disclosure.

FIG. 3G is a diagram for illustrating the method for manufacturing a semiconductor layer of the present disclosure.

FIG. 3H is a diagram for illustrating the method for manufacturing a semiconductor layer of the present disclosure.

FIG. 3I is a diagram for illustrating the method for manufacturing a semiconductor layer of the present disclosure.

FIG. 3J is a diagram for illustrating the method for manufacturing a semiconductor layer of the present disclosure.

FIG. 3K is a diagram for illustrating the method for manufacturing a semiconductor layer of the present disclosure

FIG. 4 is a diagram illustrating a manufacturing apparatus of the present disclosure.

FIG. 5A is a diagram illustrating a resist opening step of the present disclosure.

FIG. 5B is a diagram illustrating the resist opening step of the present disclosure.

FIG. 5C is a diagram illustrating the resist opening step of the present disclosure.

FIG. 6 is a diagram illustrating an example in which bumps are formed on an interposer.

### DESCRIPTION OF EMBODIMENT

Hereinafter, a semiconductor device of the present disclosure and a method for manufacturing the semiconductor device will be described with reference to the drawings.

### (Semiconductor Device)

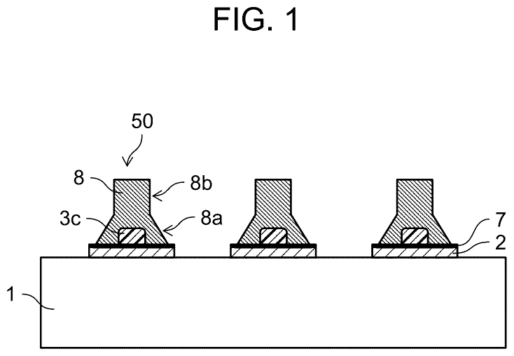

FIG. 1 is a diagram schematically illustrating a section of semiconductor device 50 of the present disclosure in an exemplary manner. Semiconductor device 50 includes semiconductor element 1, a plurality of electrode terminals 2 formed on semiconductor element 1, and bumps 8 provided on respective electrode terminals 2. Semiconductor element 1 includes a substrate having a semiconductor layer and being provided with various elements, and may be a system LSI, a memory, a CPU, or the like.

Bump 8 is made of metal such as Cu, Co, or Au, for example. Bump 8 is formed on electrode terminal 2 with seed layer 7 interposed therebetween. Seed layer 7 may be made of Ni, W, Cr, Cu, Co, or Ti, for example. Seed layer has a thickness of about 0.02 μm to 2 μm, for example.

Bump 8 has a tapered shape with a width narrowing from a side close to electrode terminal 2 toward an opposite side. FIG. 1 illustrates an example in which bump 8 includes tapering part 8a narrowing with distance from the side close to electrode terminal 2, and columnar part 8b formed as a joint of tapering part 8a and having a constant width, bump 8 having a tapered shape as a whole. Providing a tapered shape as described above relieves stress by causing the tapered part of bump 8 to be plastically deformed when semiconductor device 50 is mounted.

Buffer part 3c is further formed being covered with bump 8. More specifically, buffer part 3c is formed on electrode terminal 2 (with seed layer 7 interposed therebetween in FIG. 1), and bump 8 is formed covering a side surface and an upper surface of buffer part 3c. Thus, bump 8 is in contact with seed layer 7 and is electrically connected to electrode terminal 2 through seed layer 7 that is conductive. Bump 8 and buffer part 3c are each normally circular when viewed from above in FIG. 1.

FIG. 1 shows a desirable configuration in which a lower surface of buffer part 3c is exposed from bump 8 to be in contact with seed layer 7. Alternatively, the whole of buffer part 3c may be embedded in bump 8.

Buffer part 3c is made of a material having hardness lower than that of metal constituting bump 8, such as resin, for example. Thus, when semiconductor device 50 is mounted on a mounting substrate by flip-chip mounting, stress during the mounting is relieved by buffer part 3c. Consequently, damage to the mounting substrate and semiconductor element 1, particularly to a fragile part thereof can be reduced, and occurrence of a defect can be suppressed. Although buffer part 3c made of resin or the like may deteriorate conductivity between electrode terminal 2 and bump 8, the conductivity can be kept within an allowable range by adjusting size or the like of buffer part 3c.

Examples of a dimension of each part are described below. Electrode terminal 2 may have a diameter (dimension in a lateral direction in the drawing) of about 6 μm to 8 μm, and electrode terminals 2 may be disposed at a pitch of about 10 μm (thus, an interval between electrode terminals 2 may be about 2 μm to 4 μm). Tapering part 8a of bump 8 includes a lower part (close to electrode terminal 2) that may have a diameter that is equal to the diameter of electrode terminal 2 and is about 6 μm to 8 μm. Columnar part 8b of bump 8 preferably has a diameter that is about half the diameter of the lower part of tapering part 8a. Bump 8 may have an entire height of about 8 μm to 10 μm.

Buffer part 3c in bump 8 preferably has a diameter equal to a diameter of columnar part 8b, and the diameter is half or less of the diameter of the lower part of tapering part 8a. Thus, buffer part 3c preferably has the diameter equal to or less than about 3 μm to 4 μm. Buffer part 3c preferably has a thickness of about 0.2 μm to 3 μm, and more preferably has a thickness of about 0.5 μm to 2.0 μm from the viewpoint of exhibiting effect of relieving stress during mounting and suppressing deterioration of conductivity of bump 8.

Although all of the above dimensions are examples and desirable, the technique of the present disclosure is not limited to these numerical ranges.

### (Shape of Buffer Part)

Buffer part 3c in FIG. 1 has a width (dimension in a direction parallel to a surface of semiconductor element 1) that is constant in its height direction. That is, buffer part 3c has a cylindrical shape. However, the shape is not limited thereto.

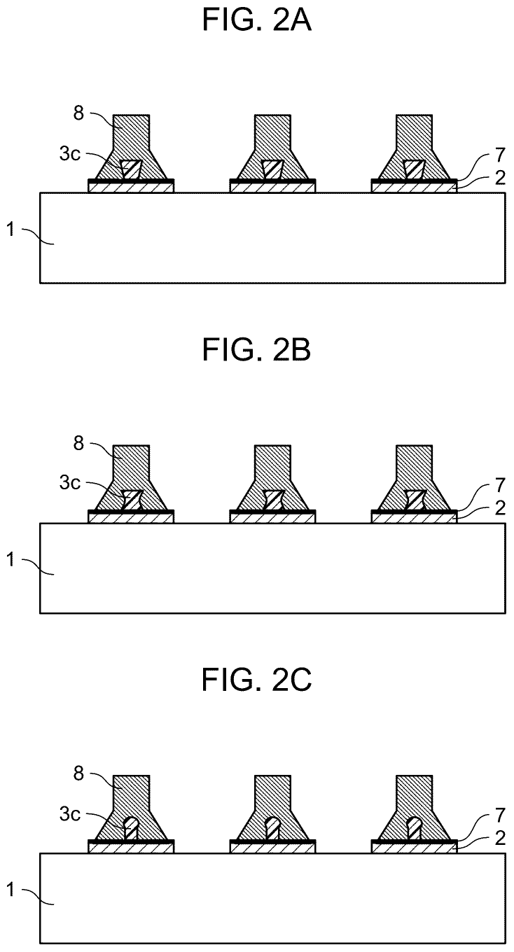

FIGS. 2A to 2C each exemplify another shape of buffer part 3c. FIG. 2A illustrates buffer part 3c having a shape with a width increasing with distance from the side close to electrode terminal 2. Conversely, the width may decrease with distance from the side close to electrode terminal 2. FIG. 2B illustrates buffer part 3c having a shape narrowed in width near the center in the height direction. FIG. 2C illustrates buffer part 3c having a shape with a top part (a side opposite to electrode terminal 2) bulging in a spherical shape. Buffer part 3c may have a shape other than that exemplified. The shape of buffer part 3c affects the effect of relieving stress and the conductivity of bump 8, so that the shape can be set in consideration of these matters.

### (Method for Manufacturing Semiconductor Device)

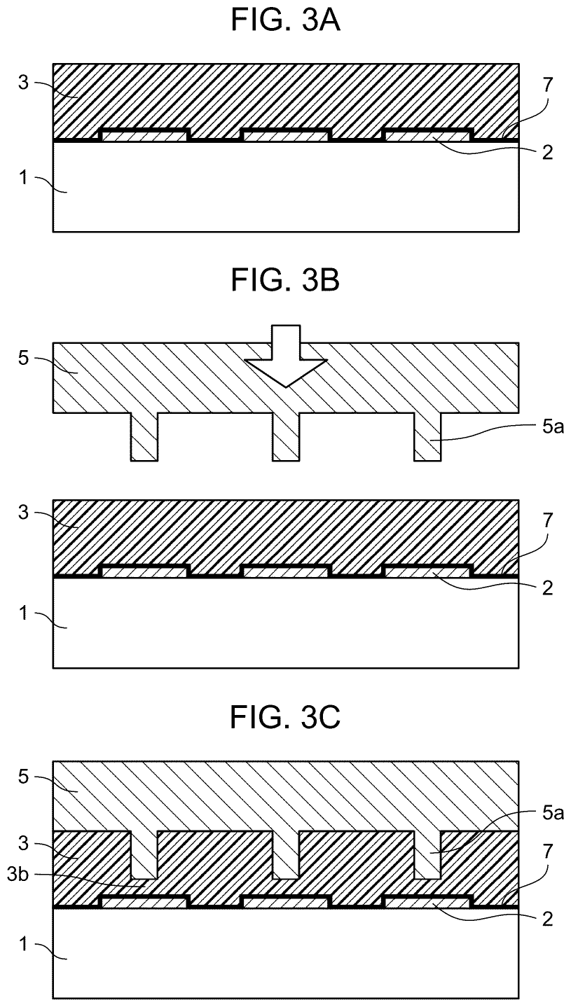

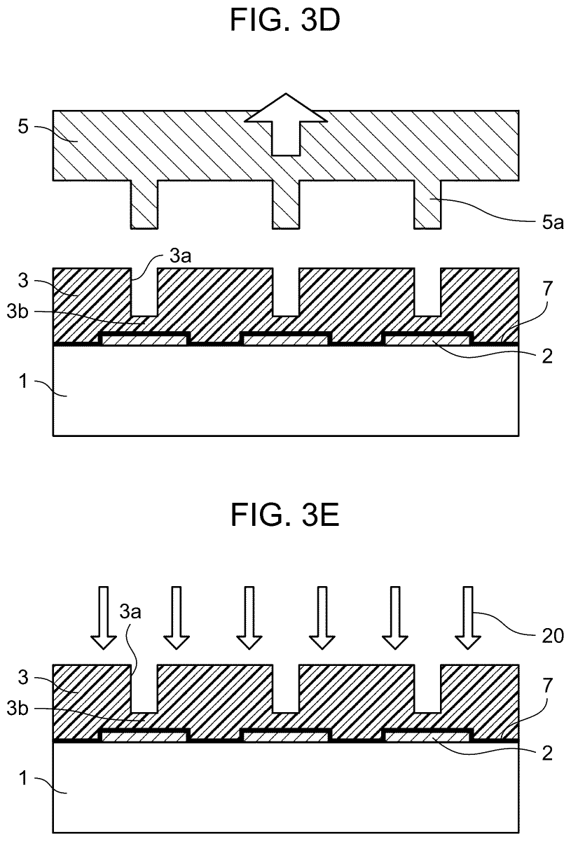

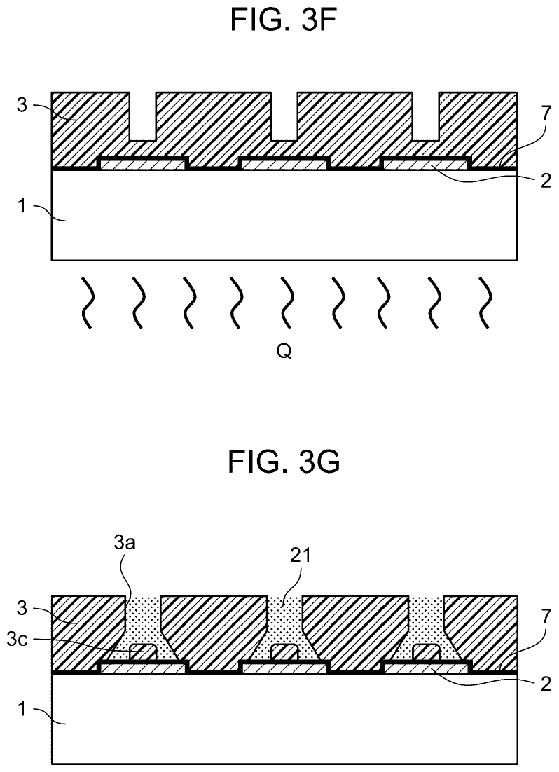

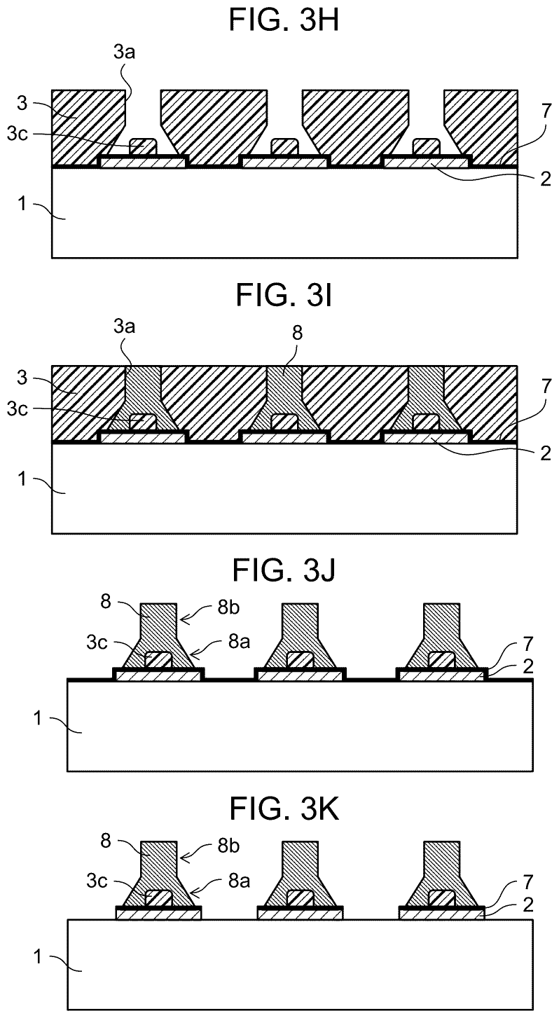

Next, a method for manufacturing semiconductor device 50, particularly, a method for forming bump 8 and buffer part 3c will be described with reference to FIGS. 3A to 3I.

FIG. 3A illustrates a step of forming resist layer 3 on semiconductor element 1. Although FIG. 3A illustrates single semiconductor element 1, the following steps may be performed in a state of a silicon wafer including a plurality of semiconductor elements 1. The silicon wafer has an outer shape with a diameter of about 30 cm, for example.

Semiconductor element 1 is provided with a plurality of electrode terminals 2. Seed layer 7 is further formed covering semiconductor element 1 including electrode terminals 2. Seed layer 7 is a thin metal layer having a thickness of about 0.02 μm to 2 μm, for example. Seed layer 7 is used as an electrode in a subsequent step of filling metal. When electroplating is used in the step of filling metal, seed layer 7 is also used as a base layer for the electroplating.

Semiconductor element 1 provided with electrode terminal 2 and seed layer 7 as described above includes resist layer 3 formed on seed layer 7. Resist layer 3 may be a photosensitive type, a thermosetting type, or a photothermal combined type resist, for example. Resist layer 3 is made of an acrylate resin, or an epoxy resin as a material, for example, and is formed with a uniform film using spin coating, a bar coater, spraying, jet dispensing, or the like.

Next, a resist opening step illustrated in FIGS. 3B and 3C will be described. This step uses imprint die 5 illustrated in FIG. 3B.

Imprint die 5 is a transfer die for forming openings 3a (see FIG. 3F, etc.) in resist layer 3, and is provided with protrusions 5a on its one surface at predetermined intervals, protrusions 5a having dimensions and shapes corresponding to openings 3a. For example, protrusions 5a are each provided facing electrode terminal 2. Protrusions 5a each may have a sectional shape of a circle, a quadrangle, an octagon, or the like.

Imprint die 5 may be made of one of quartz, glass, silicone resin, and acrylate resin, for example, or may be formed with a plurality of layers. For example, when imprint die 5 has a surface made of the silicone resin or the acrylate resin having flexibility, the surface is preferable to be able to absorb even warpage or undulation generated on semiconductor element 1.

Imprint die 5 may be formed by forming an original plate, molding a material in a flowing state, and curing the material. In this case, the original plate with recesses that are provided at intervals and in shapes, corresponding to those of openings 3a formed in resist layer 3, is used. The original plate may be formed by etching or electrical discharge machining by using silicon, nickel, quartz, or glass as a material, for example. Imprint die 5 has an external dimension larger than an external dimension of semiconductor element 1. Imprint die 5 has a rectangular shape, for example.

Imprint die 5 as described above is positioned with respect to semiconductor element 1 on which resist layer 3 is formed. As illustrated in FIG. 3B, protrusions 5a are disposed over respective electrode terminals 2. For this placement, recognition marks (not illustrated) provided on each of imprint die 5 and semiconductor element 1 may be used.

Subsequently, imprint die 5 is pressed against resist layer 3 to insert protrusions 5a into resist layer 3 on respective electrode terminals 2 as illustrated in FIG. 3C. At this time, protrusions 5a are each prevented from reaching a surface of electrode terminal 2 while a gap is left between electrode terminal 2 (precisely, seed layer 7 thereon) and a distal end of protrusion 5a. The gap is set to about 0.2 μm to 3.0 μm, and imprint die 5 is pulled up from this state (FIG. 3D).

Consequently, openings 3a are provided in resist layer 3. Openings 3a are formed perpendicularly to the surface of semiconductor element 1, and are each formed in an identical shape throughout semiconductor element 1.

Then, a part of resist layer 3 over electrode terminal 2, the part corresponding to opening 3a, is left with a thickness of about 0.2 μm to 3.0 μm to form resist residual film part 3b. Resist residual film part 3b is formed into buffer part 3c illustrated in FIG. 1. Thus, controlling a thickness and the like of resist residual film part 3b enables control of the shape of buffer part 3c, for example.

Next, a step illustrated in FIG. 3E is performed to apply light energy for reacting uniformly on the entire surface of resist layer 3 after imprint die 5 is pulled out. For example, the entire surface of resist layer 3 is irradiated with light 20 such as ultraviolet rays without passing through an exposure mask for patterning or the like.

Next, a step illustrated in FIG. 3F is performed to cure resist layer 3 to which light energy has been applied by applying thermal energy Q thereto. Examples of a curing method include a method for heating, with for example a heater, resist layer 3 from its front surface, or from a back surface of semiconductor element 1, or a method for heating the whole of semiconductor element 1 provided with resist layer 3 by putting semiconductor element 1 into a heating furnace or the like, resist layer 3 being formed by putting semiconductor element 1 into a heating furnace.

Resist residual film part 3b is further cured by heating from the back surface of semiconductor element 1 in the present exemplary embodiment, so that buffer part 3c is more easily formed in a development step.

Resist layer 3 is irradiated with light 20 from above its front surface (from above in FIG. 3E, from a side opposite to electrode terminal 2). Thus, curing reaction by heating after light energy is applied is induced stronger on a side close to the surface of resist layer 3 than others, and thus crosslink density increases. Although light 20 passes through resist layer 3, its intensity decreases toward a deep part (toward electrode terminal 2). As a result, resist layer 3 can be formed with the crosslink density decreasing toward the deep part form the side close to the surface.

Opening 3a is formed over resist residual film part 3b, so that resist residual film part 3b is irradiated with light 20 similarly to the surface of resist layer 3. Thus, resist residual film part 3b has crosslink density as high as that near the surface of resist layer 3.

Next, the development step illustrated in FIG. 3G is performed. Here, semiconductor element 1 is immersed into a developer, and developer 21 enters opening 3a. Developer 21 uniformly enters each opening 3a identical in shape throughout the entire surface of semiconductor element 1. Resist layer 3 is dissolved by developer 21, so that an inner wall of opening 3a is dissolved to expand opening 3a in its width direction.

The developer is a chemical solution having an action of dissolving resist layer 3, and may betetramethylammonium hydroxide or trimethyl-2-hydroxyethylammonium hydroxide aqueous solution, for example.

At this time, resist layer 3 is dissolved by developer 21 in accordance with its crosslink density. Specifically, a part having low crosslink density dissolves faster than a part having high crosslink density. Thus, a rate of dissolution can be controlled by controlling the crosslink density of resist layer 3.

As described above, resist layer 3 has the crosslink density decreasing toward the deep part from the side close to the surface, so that the rate of dissolution increases toward the deep part. As a result, opening 3a has a shape with width narrowing toward the surface of resist layer 3 from the deep part. FIG. 3F illustrates an example with opening 3a having a shape in which a region with a small change in width exists close to the surface, and the width remarkably changes on a side close to the deep part. When a material of resist layer 3, conditions of exposure of light 20, and the like are appropriately set, a shape as described above is also implemented.

Resist residual film part 3b has high crosslink density, and thus is not dissolved or has a small degree of dissolution even when resist residual film part 3b comes into contact with developer 21. Thus, resist residual film part 3b remains on electrode terminal 2 without being completely removed in the development step, and serves as buffer part 3c.

FIG. 3H illustrates a state in which developer 21 in opening 3a is removed. At this time, pure water, alcohol such as ethanol, acetone, or the like may be used as a cleaning liquid.

Next, opening 3a is filled with a metal material to form bump 8 covering buffer part 3c as illustrated in FIG. 3I. For this step, electrolytic plating is used, for example. That is, seed layer 7 is connected to a power source and immersed in an electrolytic plating bath to perform energization treatment. As a result, a plating film is filled in opening 3a while covering buffer part 3c.

A plating solution may be a filled plating solution of a bottom-up type, made of Cu, Co, Au, or the like. When these plating solutions are each used, wettability of the plating solution to the inner wall of opening 3a increases due to catalytic effect of Cu, Co, Au, or the like. As a result, injection of the plating solution is facilitated even in opening 3a fine in size, and is suitable for forming plating by a bottom-up method. A plating method may be electroless plating using chemical reaction instead of electrolytic plating that requires energization treatment with seed layer 7.

Here, a required height of bump 8 varies because the amount of required warpage absorption varies depending on the amount of warpage of semiconductor device 50 and a substrate equipped with semiconductor device 50. In contrast, a final shape of bump 8 can be controlled not only by the shape of opening 3a but also by conditions such as conduction treatment time in a plating step. For example, when the conduction treatment is stopped before the whole of opening 3a is filled with a plating film, bump 8 having a height smaller than a thickness of resist layer 3 can be formed. Bump 8 having a desired height can be implemented by setting conditions appropriately.

Next, a step of peeling resist layer 3 is performed as illustrated in FIG. 3J. For this step, semiconductor element 1 including resist layer 3 may be immersed in a resist stripping solution.

Finally, a part of seed layer 7, which is not covered with bump 8, is removed in a step of FIG. 3K. For this step, treatment such as wet etching or ashing may be performed. When seed layer 7 is removed in this manner, bump 8, which is a protruding electrode including tapering part 8a and columnar part 8b, is formed. Bump 8 is internally provided with buffer part 3c that is a remaining part of resist layer 3.

Here, seed layer 7 is preferably made of a material having a higher etching rate than that of bump 8. This configuration enables reducing the amount of etching on bump 8 when seed layer 7 is etched and removed, so that a shape of bump 8 is likely to be maintained. Seed layer 7 under bump 8 is allowed to remain as a conductive film.

As described above, semiconductor device 50 including bump 8 covering buffer part 3c is manufactured. For a wafer including a plurality of semiconductor elements 1, the wafer may be diced into individual chips.

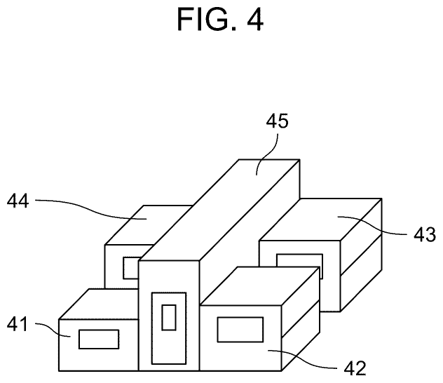

Next, a manufacturing apparatus and a manufacturing method for performing treatment on a semiconductor wafer will be described. FIG. 4 is a diagram conceptually illustrating a configuration of a manufacturing apparatus according to an exemplary embodiment. As an apparatus configuration, resist forming unit 41, resist opening unit 42, resist curing unit 43, developing unit 44, and wafer conveyance unit 45 are provided in order of steps, and a wafer processed in each unit is conveyed to a unit of a next step by the conveyance unit.

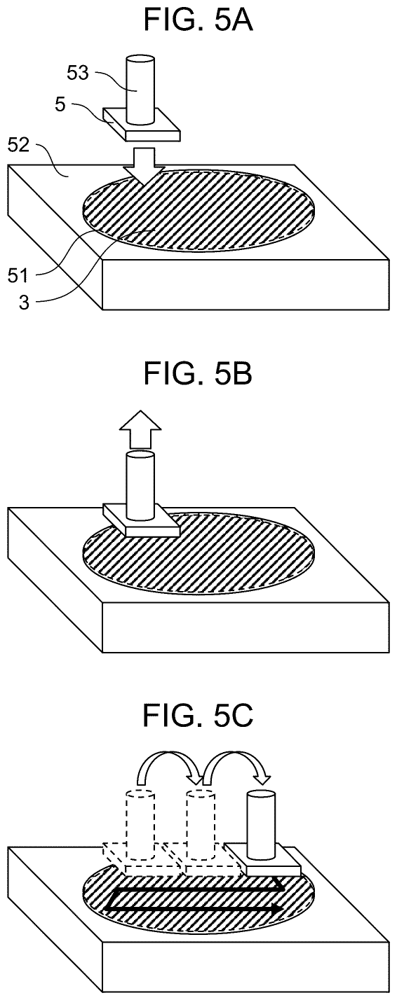

FIG. 5 is a three-dimensional view conceptually illustrating a resist opening step in the manufacturing method according to an exemplary embodiment. As illustrated in FIG. 5(a). Semiconductor wafer 51 on which resist layer 3 is formed is mounted on mounting stage 52. Resist opening is performed by aligning semiconductor wafer 51 and imprint die 5; moving imprint die 5 to a designated position (first position) on semiconductor wafer 51 with imprint head 53, and pushing imprint die 5 into resist layer 3. After that, imprint head 53 is raised to release imprint die 5 from resist layer 3 as illustrated in FIG. 5(b). Reducing imprint die 5 in size improves pattern accuracy of the die and reduces resistance during release from the die, so that resist peeling can be prevented. As illustrated in FIG. 5(c), a resist opening is formed on the entire surface of the wafer by a step-and-repeat method in which operation from alignment to release is repeated in an adjacent pattern (second position). Although imprint die 5 used at this time preferably has a size of about 20 square millimeters to 50 square millimeters from the viewpoint of productivity and shape stability, the size is not limited thereto. This method enables forming a resist stably with high accuracy, so that production with a high yield can be implemented even for a large wafer with a diameter of 300 mm.

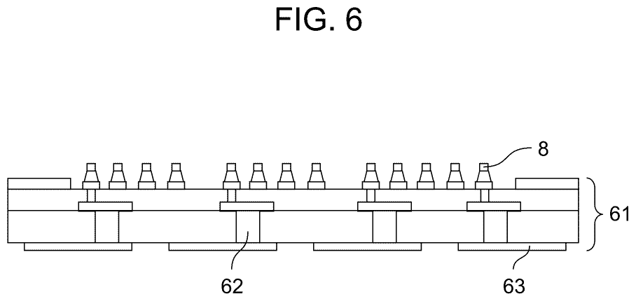

FIG. 6 is a sectional view for illustrating a structure in which bumps are formed on interposer 61 according to a second exemplary embodiment. The structure includes the bumps formed on the interposer that is used for electrically connecting front and back circuits to each other with internal wiring 62, and that is used as a highly integrated technique of three-dimensional mounting. Internal wiring 62 conducts electricity between bump 8 formed on a front surface of interposer 62 and back electrode 63 provided on a back surface of interposer 62. A semiconductor wafer or a chip is electrically bonded to a substrate or an interposer. Although bump 8 used for this structure may be formed close to the semiconductor wafer or the chip, forming bump 8 close to the substrate or interposer 61 causes an advantage such as an increase in design flexibility on a chip side. Interposer 61 is made of a material such as organic resin, Si, or glass depending on structure and characteristics of a semiconductor device.

### (Modification Related to Method for Manufacturing Semiconductor Device)

As illustrated in FIGS. 3D and 3E, and described above, imprint die 5 is pulled up from resist layer 3, and then resist layer 3 provided with opening 3a is cured. Conversely, effect of resist layer 3 may be implemented while imprint die 5 is inserted into resist layer 3, and then imprint die 5 may be pulled up.

For this method, imprint die 5 made of a light-transmissive material is used to emit ultraviolet rays or the like through imprint die 5. Then, irradiating resist layer 3 with ultraviolet rays or the like without passing through a patterning mask or the like is applied to this method similarly.

To improve releasability when imprint die 5 is pulled up from cured resist layer 3, materials with different solubility parameters are used, and the parameters are preferably different from each other by about 2.0 or more, for example. For example, when a silicone resin having a solubility parameter of 7.3 to 7.6 is used for imprint die 5, an acrylic resin having a solubility parameter of 9.5 to 12.5, an epoxy resin having a solubility parameter of 10.9 to 11.2, or the like may be used as a material of resist layer 3.

Additionally, forming a release film made of a light transmissive metal, resin, or the like on a surface of imprint die 5 can further improve releasability. Available examples of a material of the release film include nickel, indium tin oxide, silicone rubber, and fluorocarbon rubber.

When resist layer 3 is cured after imprint die 5 is pulled up, there may be a problem that the shape of resist layer 3 before curing is deformed when imprint die 5 is pulled up and before the curing is completed. This kind of problem does not occur when imprint die 5 is pulled up after resist layer 3 is cured. In contrast, when curing is performed first, imprint die 5 is required to be light-transmissive, and releasability of imprint die 5 from resist layer 3 after curing is desired to be considered. Thus, any one of the orders has an advantage.

The steps of FIGS. 3A to 3J have been described for manufacturing steps in which buffer part 3c has width (diameter) constant in the height direction as illustrated in FIG. 1. In contrast, buffer parts 3c having various sizes and shapes including those exemplified in FIGS. 2A to 2C can be implemented by adjusting a dimension of opening 3a formed in resist layer 3, the amount of light and thermal energy applied when resist layer 3 is cured, a type of developer and treatment time in the development step, and the like.

First, a size of opening 3a is determined by a dimension (diameter for a circular shape) of protrusion 5a of imprint die 5, and then a basic dimension of resist residual film part 3b is also determined.

Additionally, buffer part 3c with width varying in the height direction can be obtained by varying illuminance and irradiation time of light, and heating temperature from a surface side toward a deep side of resist layer 3 when resist layer 3 is cured.

Specifically, when treatment is performed at low illuminance for long time for exposure, difference in crosslink density in a depth direction in resist residual film part 3b decreases. This treatment implements buffer part 3c having a substantially constant diameter as illustrated in FIG. 1. On the contrary, when the treatment is performed at high illuminance for a short time, the difference in crosslink density increases as the crosslink density on the surface side increases. As a result, dissolution on the deep side is accelerated during development, and thus buffer part 3c narrowing toward semiconductor element 1 is implemented as illustrated in FIG. 2A. When thermal energy is applied to extremely increase the crosslink density in an upper part of resist residual film part 3b by varying temperature between the deep side and the surface side, a shape narrowed at a central part in the height direction as illustrated in FIG. 2B can be implemented. Additionally, a shape as illustrated in FIG. 2C, having a spherical top part and a columnar bottom part, can be implemented by setting light energy for low illuminance and varying thermal energy in a vertical direction.

Although manufacturing of a bump using imprinting has been described in the present exemplary embodiment, the present invention is not limited thereto, and rewiring (RDL) may be performed on a substrate or an LSI using the imprinting.

### INDUSTRIAL APPLICABILITY

The technique of the present disclosure is useful as a semiconductor device and a method for manufacturing the semiconductor device because damage to a mounting substrate or the like due to stress during mounting can be reduced.

### REFERENCE MARKS IN THE DRAWINGS

1 semiconductor element
2 electrode terminal
3 resist layer
3a opening
3b resist residual film part
3c buffer part
5 imprint die
5a protrusion
7 seed layer
8 bump
8a tapering part
8b columnar part
20 light
21 developer
50 semiconductor device

1. A semiconductor device comprising:
a semiconductor element having a plurality of electrode terminals;
a bump formed on each of the plurality of electrode terminals and having a tapering part narrowing with distance from a side close to the electrode terminal; and
a buffer part covered with the bump.

2. The semiconductor device according to claim 1, wherein the buffer part is made of resist resin.

3. A method for manufacturing a semiconductor device, the method being performed on a semiconductor element including a plurality of electrode terminals and a resist layer covering each of the plurality of electrode terminals, the method comprising:
a step of providing openings in the resist layer by inserting protrusions provided on an imprint die into the resist layer on the plurality of electrode terminals;
a step of curing the resist layer by applying energy to the resist layer; and
a step of widening each of the openings in a width direction by causing the resist layer provided with the opening to react with a developer,
the step of providing the openings being performed to cause a distal end of each of the protrusions to be prevented from reaching a surface of corresponding one of the electrode terminals to leave a gap.

4. The method for manufacturing a semiconductor device according to claim 3, wherein the step of providing the openings is performed to form a resist residual film part including the resist layer in the gap on a surface of each of the electrode terminals.

5. The method for manufacturing a semiconductor device according to claim 3, wherein the step of widening the openings in the width direction is performed to mold each of the openings in a reverse tapered shape widening toward corresponding one of the electrode terminals.

6. The method for manufacturing a semiconductor device according to claim 3, further comprising a step of forming a seed layer covering the plurality of electrode terminals before the resist layer is formed,
wherein the resist layer is formed on the seed layer.

7. The method for manufacturing a semiconductor device according to claim 3, wherein the step of curing the resist layer is performed to irradiate an entire surface of the resist layer with ultraviolet rays without passing through a mask.

8. A semiconductor manufacturing apparatus comprising:
an imprint die including protrusions forming openings in a resist layer covering a semiconductor element including a plurality of electrode terminals; and
a head configured to pressurize the imprint die,
wherein the head pressurizes the protrusions while leaving the resist layer between each of the electrode terminals and corresponding one of the protrusions when the protrusions are each inserted into a first position of the resist layer.

9. The semiconductor manufacturing apparatus according to claim 8, further comprising a heater provided close to a stage on which the semiconductor element is disposed, the heater being configured to heat the resist.

10. The semiconductor manufacturing apparatus according to claim 8, wherein the head pressurizes the imprint die against the resist layer at a second position adjacent to the first position.

11. A semiconductor manufacturing apparatus unit comprising:
a resist forming unit configured to form a resist layer covering each of a plurality of electrode terminals on a semiconductor element including the plurality of electrode terminals;
a resist opening unit configured to provide openings in the resist layer by inserting protrusions provided on an imprint die into the resist layer on each of the plurality of respective electrode terminals;
a resist curing unit configured to cure the resist layer by applying energy to the resist layer;
a developing unit configured to widen each of the openings in a width direction by causing the resist layer provided with the openings to react with a developer; and
a wafer conveyance unit that conveys the semiconductor element among the resist forming unit, the resist opening unit, the resist curing unit, and the developing unit.
